(19) United States
(12) Patent Application Publication
(10) Pub. No.: US 2020/0253048 A1
(43) Pub. Date: Aug. 6, 2020

(54) METHOD OF THERMOFORMING INTEGRATED TRANSPARENT CONDUCTIVE FILMS

(71) Applicant: SABIC Global Technologies B.V., Bergen of Zoom (NL)

(72) Inventors: Zhe Chen, Shanghai (CN); Jing Chen, Shanghai (CN); Yonglei Xu, Shanghai (CN); Yuzhen Xu, Shanghai (CN)

(21) Appl. No.: 16/838,101

(22) Filed: Apr. 2, 2020

Related U.S. Application Data
(62) Division of application No. 15/763,547, filed on Mar. 27, 2018.
(60) Provisional application No. 62/233,570, filed on Sep. 28, 2015.

(51) Int. Cl. H05K 1/09; B29C 51/14; B32B 27/16; B32B 27/08; H05K 3/00; B32B 27/26

(52) U.S. Cl. CPC H05K 1/095; B32B 2307/202; B32B 27/16; B32B 27/08; H05K 3/0014; B32B 27/26; H05K 1/097; B32B 2369/00; B32B 2327/12; B32B 2325/00; B32B 2323/10; B32B 2323/04; B32B 2457/206; B32B 2457/08; H05K 2201/0108; B32B 2255/205; B32B 2457/12; B32B 2255/10; B32B 2457/208; B32B 2457/202; H05K 2201/0129; B32B 2457/20; B29C 51/14

(57) ABSTRACT

A method of thermoforming an article from an integrated transparent conductive film, comprising: applying an ultraviolet curable transfer coating to a first surface of a recipient substrate or to a first surface of a donor substrate, wherein the first surface of the donor substrate includes a conductive coating coupled thereto; pressing the first surface of the recipient substrate and the first surface of the donor substrate together to form a stack; heating the stack and activating the ultraviolet curable transfer coating with an ultraviolet radiation source; removing the donor substrate from the stack leaving a transparent conductive layer, wherein the ultraviolet curable transfer coating remains adhered to the first surface of the recipient substrate and to the conductive coating; laser etching an electrical circuit onto a transparent conductive layer second surface to form an integrated transparent conductive film; and thermoforming the integrated transparent conductive film to form the article.

### CROSS-REFERENCE TO RELATED APPLICATIONS

This application is a divisional of U.S. application Ser. No. 15/763,547, filed Mar. 27, 2018, which is a national stage application of International Application No. PCT/IB2016/055781, filed Sep. 27, 2016, which claims benefit of U.S. Provisional Application No. 62/233,570, filed Sep. 28, 2015, all of which are incorporated herein by reference in their entirety.

### BACKGROUND

Transparent conductive layers can be useful in a variety of electronic devices. These layers can provide a number of functions such as electromagnetic interference shielding and electrostatic dissipation. These layers can be used in many applications including, but not limited to, touch screen displays, wireless electronic boards, photovoltaic devices, conductive textiles and fibers, organic light emitting diodes, electroluminescent devices, and electrophoretic displays, such as e-paper.

Transparent conductive layers can include a network-like pattern of conductive traces formed of metal. The conductive layer can be applied to a substrate as a wet coating which can be sintered to form these networks. However, some substrate materials can be damaged by a sintering process. Additionally, it can be difficult to thermoform articles from the substrates with the conductive layers and conductivity can suffer from substrates which are thermoformed.

Indium tin oxide (ITO) on a polymer, typically polyethylene terephthalate, or glass substrate is conventionally used for transparent conductive layers. However, such systems lack flexibility and formability. Other systems that use alternative materials to ITO such as graphene, metal mesh, silver nanowires, and carbon nanotubes either cannot be thermoformed, or can only be stretched under extreme high temperatures that cannot be applied to plastic substrates or integrated circuits. With the developments in flexible and wearable electronics, a need exists for transparent conductive layers that are flexible and formable.

Thus, there is a need in the art for a flexible transparent film including a conductive layer wherein the film can be thermoformed without a loss in electrical and mechanical properties.

### BRIEF DESCRIPTION

Disclosed herein are integrated transparent conductive films for thermal forming applications and methods of making.

An integrated transparent conductive film, comprises: a substrate comprising a transparent thermoplastic material, wherein the substrate includes a substrate first surface and a substrate second surface; a transparent conductive layer disposed adjacent to the substrate, wherein the transparent conductive layer includes a transparent conductive layer first surface disposed on the substrate first surface; and an electrical circuit disposed on a transparent conductive layer second surface; wherein the integrated transparent conductive film has a functional electrical circuit after thermoforming.

A method of thermoforming an article from an integrated transparent conductive film, comprises: heating the integrated transparent conductive film to a formable temperature in a mold, wherein the integrated transparent conductive film comprises a substrate comprising a transparent thermoplastic material, wherein the substrate includes a substrate first surface and a substrate second surface; a transparent conductive layer disposed adjacent to the substrate, wherein the transparent conductive layer includes a transparent conductive layer first surfaced disposed on the substrate first surface; and an electrical circuit etched onto a transparent conductive layer second surface; thermoforming the integrated transparent conductive film to the article comprising the mold shape; cooling the formed article; and removing the formed article form the mold; wherein the formed article has a functional electrical circuit after thermoforming.

A method of thermoforming an article from an integrated transparent conductive film, comprises: applying an ultraviolet curable transfer coating to a first surface of a recipient substrate or to a first surface of a donor substrate, wherein the first surface of the donor substrate includes a conductive coating coupled thereto; pressing the first surface of the recipient substrate and the first surface of the donor substrate together to form a stack, wherein the ultraviolet curable transfer coating is disposed therebetween; heating the stack and activating the ultraviolet curable transfer coating with an ultraviolet radiation source; removing the donor substrate from the stack leaving a transparent conductive layer, wherein the ultraviolet curable transfer coating remains adhered to the first surface of the recipient substrate and to the conductive coating; laser etching an electrical circuit onto a transparent conductive layer second surface to form an integrated transparent conductive film; and thermoforming the integrated transparent conductive film to form the article, wherein the article includes a functional electrical circuit after thermoforming.

The above described and other features are exemplified by the following figures and detailed description.

### BRIEF DESCRIPTION OF THE DRAWINGS

Refer now to the figures, which are exemplary embodiments, and wherein the like elements are numbered alike.

FIG. 1 is an illustration of a cross-sectional view of an integrated transparent conductive film including a conductive layer transferred thereto.

FIG. 2 is an illustration of an embodiment of a method disclosed herein to produce a thermoformed article from an integrated transparent conductive film.

FIG. 3. is an illustration of an embodiment of a method of thermoforming the integrated transparent conductive film disclosed herein.

FIG. 4. is an illustration of the various testing locations on the thermoformed part including the integrated transparent conductive film.

FIG. 5 is a photographic illustration of a thermoformed article of the integrated transparent conductive film.

FIG. 6 is a front view of a center stack display for use in vehicular applications.

### DETAILED DESCRIPTION

It can be difficult to thermoform multilayer sheets or films that include a conductive layer, much less a conductive layer including an electrical circuit disposed thereon, since the conductive layer can be brittle and therefore, can break easily. Additionally, if able to be thermoformed, the functionality of the electric circuit may be compromised, and the conductivity of the formed film can be lower than that of a film having an identical structure that has not been thermoformed. Disclosed herein is an integrated transparent conductive film, as well as a method of thermoforming the integrated transparent conductive film to form an article including a functional electrical circuit. In the integrated transparent conductive films disclosed herein, the electrical circuit can be directly etched onto the transparent conductive layer (i.e., can be directly etched without the use of a silver paste). In the integrated transparent conductive films disclosed herein, the electrical circuit can be etched onto the transparent conductive layer with the use of a paste, e.g., a silver paste.

The integrated transparent conductive film can include a substrate, a transparent conductive layer disposed adjacent to the substrate, with or without an electrical circuit disposed on the transparent conductive layer. The substrate can include a substrate first surface and a substrate second surface, where the substrate second surface can be an outermost surface of the integrated film. A transparent conductive layer is disposed adjacent to the substrate, wherein the transparent conductive layer includes a transparent conductive layer first surfaced disposed on the substrate first surface. An electrical circuit is formed by etching patterns on the transparent conductive layer, wherein the integrated transparent conductive film has a functional electrical circuit after thermoforming.

The substrate can be any shape. The substrate can have a substrate first surface and a substrate second surface (e.g., a substrate first surface and a substrate second surface). The substrate can include a polymer. The first surface of the substrate can comprise a first polymer. The second surface of the substrate can comprise a second polymer. The first surface of the substrate can be disposed opposite the second surface of the substrate. The first surface of the substrate can consist of the first polymer. The second surface of the substrate can consist of the second polymer. The first surface of the substrate can consist of the first polymer and the second surface of the substrate can consist of the second polymer. The first polymer and the second polymer can be co-extruded to form the substrate. The first polymer and the second polymer can be different polymers, e.g. can comprise different chemical compositions. The substrate can be flat and can include the first surface and the second surface where the second surface can be disposed opposite the first surface, such as co-extruded forming opposing sides of the substrate. The substrate can be flexible.

The substrate can be formed by any polymer forming process. For example, a substrate can be formed by a co-extrusion process. The substrate can be co-extruded into a flat sheet. The substrate can be co-extruded into a flat sheet including a first surface comprising a first polymer and a second surface comprising a second polymer having a different chemical composition than the first polymer. The substrate can be co-extruded into a flat sheet including a first surface consisting of only a first polymer and a second surface consisting of only a second polymer having a different chemical composition than the first polymer. The substrate can be co-extruded into a flat sheet including a first surface consisting of polycarbonate and a second surface consisting of poly (methyl methacrylate) (PMMA).

The substrate can include flexible films that can be formed, molded, and withstand torsion and tension. The conductive layer can be applied to a substrate using any suitable wet coating process, such as spray coating, dip coating, roll coating, and the like. The films can be formed using roll to roll manufacturing or a similar process.

The transparent conductive layer can contain an electromagnetic shielding material. The conductive layer can include a conductive material. Conductive materials can include pure metals such as silver (Ag), nickel (Ni), copper (Cu), metal oxides thereof, combinations comprising at least one of the foregoing, or metal alloys comprising at least one of the foregoing, or metals or metal alloys produced by the Metallurgic Chemical Process (MCP) described in U.S. Pat. No. 5,476,535. Metals of the conductive layer can be nanometer sized, e.g., such as where 90% of the particles can have an equivalent spherical diameter of less than 100 nanometers (nm). The metal particles can be sintered to form a network of interconnected metal traces defining randomly shaped openings on the substrate surface to which it is applied. The sintering temperature of the conductive layer can be 300° C. which can exceed the heat deflection temperature of some substrate materials. After sintering, the surface resistance of the conductive layer can be less than or equal to 0.1 ohm per square (ohm/sq). The conductive layer can have a surface resistance of less than 1/10 of the surface resistance of an indium tin oxide coating. The conductive layer can be transparent.

Unlike networks formed of nanometer sized metal wires, the conductive network formed of nanometer sized metal particles can be bent without reducing the conductivity and/or increasing the electrical resistance of the conductive network. For example, networks of metal wires can separate at junctions when bent, which can reduce the conductivity of the wire network, whereas the metal network of nanometer sized particles can deform elastically without separating traces of the network, thereby maintaining the conductivity of the network.

The conductive layer can be directly coated on the substrate. The substrate can be the substrate on which the conductive layer is originally formed or can be a substrate to which the conductive layer is transferred after formation. For example, the conductive layer can be disposed adjacent to a surface of a substrate, e.g., a donor substrate. The conductive layer can be formed on a substrate, e.g., donor substrate, and after formation, the coating can be transferred to another substrate, e.g., recipient substrate. The conductive layer can be applied to a substrate using any wet coating technique, e.g., screen printing, spreading, spray coating, spin coating, dipping, and the like.

In an embodiment, the conductive layer can be formed on a donor substrate, the ultraviolet curable transfer coating layer can be applied to the donor substrate or to the recipient substrate, the donor and recipient substrates can be heated and pressed together such that the ultraviolet curable transfer coating layer can be sandwiched between the substrates, and the donor substrate can be removed leaving the conductive layer and the ultraviolet curable transfer coating layer on the recipient substrate.

The ultraviolet curable transfer coating layer can be cured. Curing the ultraviolet curable transfer coating layer can include waiting, heating, drying, exposing to electromagnetic radiation (e.g., electromagnetic radiation (EMR) in the UV spectrum), or a combination of one of the foregoing. If present, the donor substrate can be removed, leaving the ultraviolet curable transfer coating layer and conductive layer adhered to a surface of the film.

The donor substrate can include a polymer. The adhesion between the ultraviolet curable transfer coating layer and a donor or recipient substrate can be determined following ASTM D3359. The adhesion, per ASTM D3359, between the ultraviolet curable transfer coating layer and the polymer of the donor substrate can be 0B. The adhesion, per ASTM D3359, between the conductive layer and the donor substrate can be 0B. The adhesion between the ultraviolet curable transfer coating layer and the polymer of the recipient substrate can be 5B. The adhesion between the conductive layer and the polymer of the recipient substrate can be 5B. The ultraviolet curable transfer coating layer can have a greater adhesion for the polymer of the recipient substrate than for the polymer of the donor substrate.

The ultraviolet curable transfer coating layer can be disposed adjacent to a surface of the substrate (e.g., dispersed across the surface of the substrate) to facilitate the transfer of a conductive. The ultraviolet curable transfer coating layer can abut a surface of the substrate. The ultraviolet curable transfer coating layer can be used to transfer the conductive layer from a donor substrate to a recipient substrate. The ultraviolet curable transfer coating layer can have a greater adhesion to the recipient substrate than to the donor substrate, such that when the ultraviolet curable transfer coating layer is sandwiched between the recipient substrate and the donor substrate and the donor substrate is removed, the ultraviolet curable transfer coating layer can preferentially adhere to the recipient substrate rather than to the donor substrate. The ultraviolet curable transfer coating layer can be in mechanical communication with both the nano-metal network of the conductive layer and a surface of a substrate.

The ultraviolet curable transfer coating layer can be disposed on a surface of the conductive layer. For example, the substrate can be a donor substrate to which a conductive layer is adhered or can be a recipient substrate that can receive the conductive layer from the donor substrate. The ultraviolet curable transfer coating layer can be applied to the conductive layer, which can be adhered to a donor substrate, such that the conductive layer can be disposed between the ultraviolet curable transfer coating layer and the donor substrate. The donor substrate including a conductive layer and an ultraviolet curable transfer coating layer can be coupled to a recipient substrate such that the conductive layer can abut a surface of the recipient substrate and the ultraviolet curable transfer coating layer can be sandwiched between the conductive layer and a surface of the recipient substrate. The donor substrate can then be removed, and the ultraviolet curable transfer coating layer and the conductive layer can be left adhered to the recipient substrate. The ultraviolet curable transfer coating layer can at least partially surround the conductive layer. The conductive layer can be at least partially embedded in the ultraviolet curable transfer coating layer, such that a portion of the ultraviolet curable transfer coating layer can extend into an opening in the nano-metal network of the conductive layer.

The donor substrate, including the conductive layer, can be coupled to the ultraviolet curable transfer coating layer where the conductive layer can be disposed on the surface of the recipient substrate, and the donor substrate can be removed such that the conductive layer can remain coupled to the ultraviolet curable transfer coating layer and adjacent to the recipient substrate. The donor substrate can include a polymer that is capable of withstanding the conductive layer sintering temperature without damage.

For example, an integrated transparent conductive film can also be formed by transferring the conductive layer from a donor substrate to a recipient substrate. The substrates can be heated. The substrates can be heated to a temperature of greater than or equal to 70° C. The substrates can be heated to a temperature of 70° C. to 95° C. The ultraviolet curable transfer coating layer can be applied to a surface of the donor substrate. The ultraviolet curable transfer coating layer can be applied to a surface of the conductive layer. The ultraviolet curable transfer coating layer can be applied to a surface of the recipient substrate. The ultraviolet curable transfer coating layer can be applied using any wet coating technique. The donor and recipient substrates can be pressed together to form a stack, where the ultraviolet curable transfer coating layer and the conductive layer can be sandwiched between surfaces of the donor and recipient substrates. Pressing can be performed by any suitable device, e.g., roller pressing, belt pressing, double belt pressing, stamping, die pressing, or a combination comprising at least one of the foregoing. The pressing device can be used to remove air bubbles trapped between the substrates. The pressing can include pressing the donor and recipient substrates together to a pressure of greater than 0.2 megaPascal (MPa), for example, 0.2 MPa to 1 MPa, or, 0.2 MPa to 0.5 MPa, or, 0.3 MPa, while the conductive layer and ultraviolet curable transfer coating layer are sandwiched in between the donor and recipient substrates. The stack of substrates can be exposed to heat, ultraviolet (UV) light or some other cure initiator to cure the ultraviolet curable transfer coating layer. The donor substrate can be removed, leaving behind the recipient substrate having a securely adhered conductive layer including the ultraviolet curable transfer coating layer.

A substrate can optionally include a substrate coating disposed on a surface of the substrate. For example, the substrate coating can be disposed on an outermost surface of the substrate, e.g., the first surface. The substrate coating can be disposed on two opposing surfaces of the substrate. The substrate coating can provide a protective portion to the substrate. The protective portion, such as an acrylic hard coat, can provide abrasion resistance to the underlying substrate. The protective portion can be disposed adjacent to a surface of the substrate. The protective portion can abut a surface of the substrate. The protective portion can be disposed opposite the conductive layer. The protective portion can include a polymer. In an embodiment, a substrate coating can include a polymeric coating offering good pencil hardness (e.g., 4-5H measured according to ASTM D3363 on polymethyl methacrylate or HB-F measured according to ASTM D3363 on polycarbonate) and chemical/abrasion resistance, together with desirable processing characteristics. For example, the substrate coating can include a coating such as a LEXAN™ OQ6DA film, commercially available from SABIC's Innovative Plastics Business or a similar acrylic based or silicon based coating, film, or coated film, which can provide enhanced pencil hardness, enhanced chemical resistance, variable gloss and printability, enhanced flexibility, and/or enhanced abrasion resistance. The coating can be 0.1 millimeter (mm) to 2 mm thick, for example, 0.25 mm to 1.5 mm, or, 0.5 mm to 1.2 mm thick. The coating can be applied on one or more sides of the substrate. For example, the substrate coating can include an acrylic hard coat.

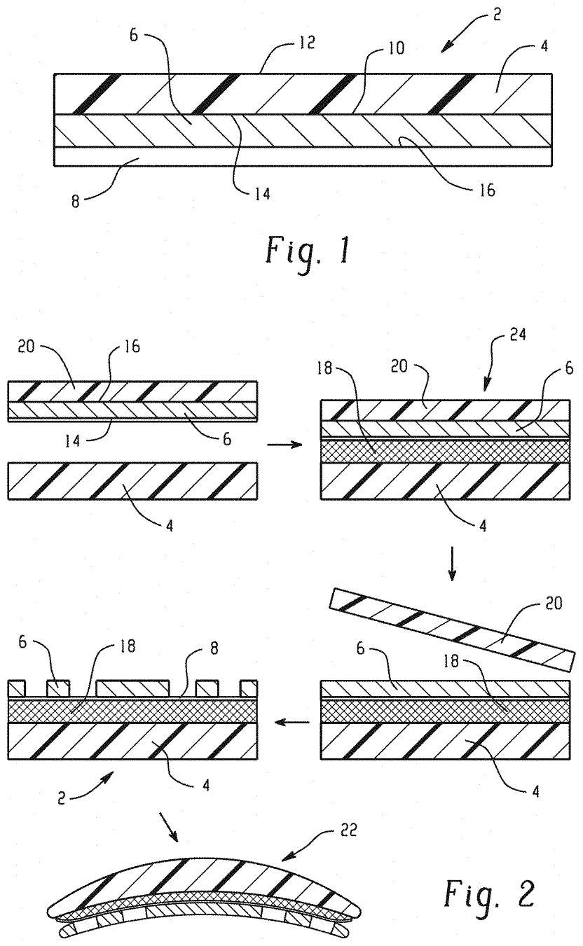

FIG. 1 is an illustration of an integrated transparent conductive film 2 including a substrate 4, transparent conductive layer 6, and an electrical circuit 8. The substrate can include a substrate first surface 10 and a substrate second surface 12. The transparent conductive layer 6 can be disposed adjacent to the substrate first surface 10. The transparent conductive layer 6 includes a transparent conductive layer first surface 14 and a transparent conductive layer second surface 16. The transparent conductive layer first surface 14 can be applied directly to the substrate first surface 10. The transparent conductive layer first surface 14 can be applied to the substrate first surface 10 via an ultraviolet curable transfer coating layer 18 (FIG. 2).

As shown in FIG. 2, the integrated transparent conductive film 2 and article 22 can be prepared by applying a conductive layer 6 on a donor substrate 20, wherein the donor substrate 20 is adjacent to the conductive layer second surface 16. An ultraviolet curable coating layer 18 can be applied to a substrate 4, such as a recipient substrate. The ultraviolet curable coating layer 18 may be applied to the substrate first surface 10. Alternatively, or in addition to, the ultraviolet curable coating layer 18 can be applied to the conductive layer first surface 14. The recipient substrate, the ultraviolet curable coating layer, and the donor substrate can be pressed together to form a stack 24. The stack 24 can be heated and the ultraviolet cured coating layer can be activated with an ultraviolet radiation source. The donor substrate 20 can be removed from the stack, wherein the ultraviolet curable coating layer 18 adheres to the recipient substrate 4 and the conductive layer 6.

An electrical circuit can be disposed on the transparent conductive layer to form the integrated transparent conductive film. For example, the electrical circuit can be disposed on a transparent conductive layer second surface, wherein a transparent conductive layer first surface is disposed on the substrate first surface. The electrical circuit can be deposited, applied, or created on the conductive layer second surface by any suitable means. For example, the electrical circuit can be laser etched on the transparent conductive layer.

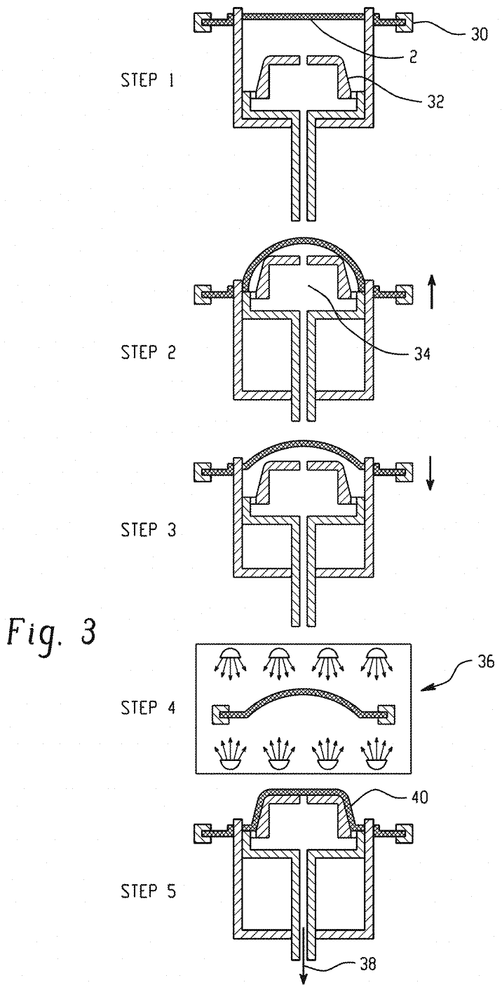

The integrated transparent conductive film can then be thermoformed to form a thermoformed article. As shown in FIG. 3, thermoforming the integrated transparent conductive film to form an thermoformed article can include placing the integrated transparent conductive film 2 on a clamp 30 of a mold 32, fixing the integrated transparent conductive film 2 to the clamp 30, pushing integrated transparent conductive film 2 out of the clamp 30 by raising the mold 32 creating a sealed air chamber 34 therein, lowering the mold 32, and heating 36 the integrated transparent conductive film 2 while simultaneously beginning the vacuum forming 38 and raising the mold 32 to form the thermoformed article 40.

For example, the integrated transparent conductive film may be pushed out of the clamp by raising the mold before heating the film, such that the tensile stress decreases during the forming process. After the mold is lowered, the film can be heated. For example, the heater can be set to 300° C. to 500° C. In an example, the heater can be set to 400° C., and the film surface temperature can reach 150° C. to 200° C., such as 160° C. to 180° C., and 160° C. to 175° C. The heated film is then subjected to vacuum and the mold is raised to form the thermoformed article.

The integrated transparent conductive film has a functional electrical circuit after thermoforming. The electrical circuit can be conductive after thermoforming. The electrical circuit can be closed after thermoforming. In other words, the present method allows an electrical circuit to be applied to a conductive layer to form an integrated film, and thermoforming the film into a desired shape, wherein the electrical circuit remains functional even after thermoforming.

The thickness of the integrated transparent conductive film can be at least 0.001 millimeters (mm), at least 0.01 mm, at least 0.1 mm, or at least 1 mm. The thickness of the integrated transparent conductive film can be less than or equal to 5 mm, less than or equal 4 mm, less than or equal 3 mm, or less than or equal 2 mm. For example, the thickness of the integrated transparent conductive film can be 0.01 mm to 5 mm, 0.01 mm to 3 mm, 0.1 to 4 mm, or 0.1 to 5 mm, among others.

The integrated transparent conductive film and article can transmit greater than or equal to 50% (e.g. 50 percent transmittance), greater than or equal to 70%, or greater than or equal to 80% of incident visible light (e.g., electromagnetic radiation having a frequency of 430 THz to 790 THz), for example, 50% to 100%, 60% to 100%, 70% to 100%, or, 80% to 100%. A transparent polymer, substrate, coating, film, and/or material of the sheet or film can transmit greater than or equal to 50% of incident EMR having a frequency of 430 THz to 790 THz, for example, 75% to 100%, or, 90% to 100%. Transparency is described by two parameters, percent transmission and percent haze. Percent transmittance and percent haze for laboratory scale samples can be determined using ASTM D1003, Procedure A using CIE standard illuminant C using a Haze-Gard test device (e.g., BYK Gardner Haze-Gard Plus). ASTM D1003 (Procedure B, Spectrophotometer, using illuminant C with diffuse illumination with unidirectional viewing) defines percent transmittance as:

$$\% T = ( \frac{I}{{I}_{o}} ) \times 100 \% \qquad [ 1 ]$$

wherein: I is the intensity of the light passing through the test sample and L is the Intensity of incident light.

The article can be any suitable article including an electric circuit. The article can be a touch screen including the integrated conductive film. These integrated transparent conductive films can be used in many applications including, but not limited to, touch screen displays, curved touch sensor, wireless electronic boards, photovoltaic devices, conductive textiles and fibers, organic light emitting diodes, electroluminescent devices, and electrophoretic displays, such as e-paper.

As described in U.S. Patent Publication No. 2014/0252670, which is incorporated by reference herein, in its entirety, touch sensitive switches are used in applications such as home appliances (e.g., touch panels on stoves, washers and dryers, blenders, toasters, etc.), and portable devices (e.g., IPOD, telephones). In-molded capacitive switches described herein (e.g., buttons which can realized cap sense function after a circuit is laser etch thereto) can be used in a number of different configurations and geometries. For example, conductors and electrodes can be formed into protruding or recessed shapes (for items such as knobs and buttons). The switch components can be printed onto a flat film and then formed to the desired shape. In addition, multi-segment sensing zones can be used.

The integrated transparent conductive films described herein can be used in many different applications. These applications fall into categories which include general purpose multi-touch input, replacing simpler discrete controls such as buttons or sliders, and measuring pressure distributions. In the first category are applications such as phone, tablet, laptop, and display touch panels and also writing pads, digitizers, signature pads, track pads, and game controllers. In the second category are applications in toys, musical instruments (such as electric pianos, drums, guitars, and keyboards), digital cameras, hand tools, and replacing dashboard controls on automobiles and other vehicles (e.g., a center stack display). In the third category are applications in scientific/industrial measurement (such as measuring the shape or flatness of a surface), medical measurement (such as measuring the pressure distribution of a person's feet or their movement in a bed), and robotics applications (such as coating a robot with sensors to give it the ability to feel touch and contact).

It is noted that there are many possible applications beyond the ones that are listed, and many applications that may use the buttons containing sensors in different modalities. As described in U.S. Pat. No. 9,001,082, which is incorporated by reference herein, in its entirety, for example, the integrated transparent conductive film can be molded on a flexible substrate, allowing the film to be embedded into flexible devices.

Some example applications include creating a flexible phone or a flexible tablet, the wristband of a digital watch or bracelet, and the sole of a shoe or sneaker or into clothing to track a user's motions, detect impacts or provide a portable user-interface. The integrated thermoplastic conductive films disclosed herein can also be designed such that they can be cut or folded to wrap around complex surfaces such as a robot fingertip. Or, they can be directly manufactured onto complex surfaces. In short, almost any surface can be imbued with touch sensitivity by layering one of the present invention sensors on, behind, or inside of it.

Laser Direct Structuring (LDS) and plating can also be utilized for adding electrical circuit paths to electronic products including the integrated transparent conductive layer disclosed herein. Such products can include, but are not limited, to mobile phone and notebook antennas, or molded interconnect devices (MIDs).

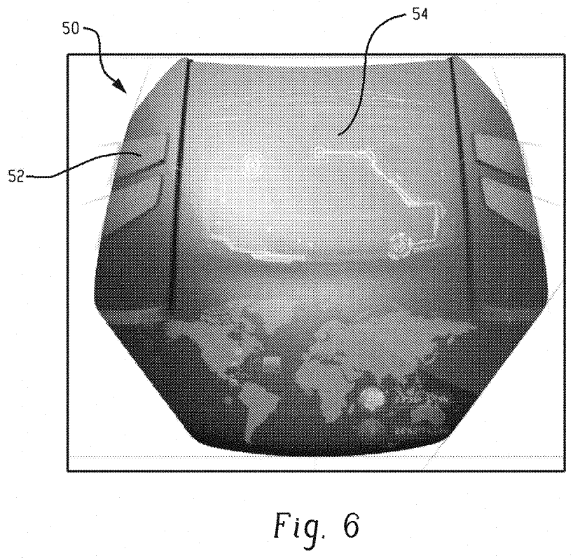

FIG. 6 illustrates an example of a center stack display 50 which can include buttons 52 that include the integrated transparent conductive layer disclosed herein. Center stack displays are provided between driver and passenger seats in a cockpit of a vehicle. Two functions of the center stack display are to inform passengers of the general state of the vehicle and to permit passengers to adjust accessories influencing passenger comfort such as temperature and radio volume, for example. Center stacks include at least one digital display (see e.g., U.S. Pat. No. 8,142,030, which is incorporated by reference herein, in its entirety). The digital display is usually a flat, rectangular, thin film transistor (TFT) glass display or a liquid crystal display (LCD). Optionally, the display can include a touch screen overlay or can be controlled by a large number of switches. The display 54 can include a number of buttons 52 to allow a user to control various functions inside the vehicle.

The integrated transparent conductive film can include a protective portion, such as an abrasion resistant coating. The protective portion, such as an acrylic hard coat, can provide abrasion resistance to the underlying conductive layer, electrical circuit, and substrate. The protective portion can be disposed adjacent to a surface of the substrate. The protective portion can abut a surface of the substrate. The protective portion can be disposed on the conductive layer or on the electrical circuit. The protective portion can include a polymer. In an embodiment, a substrate coating can include a polymeric coating offering good pencil hardness (e.g., 4-5H measured according to ASTM D3363 on polymethyl methacrylate or HB-F measured according to ASTM D3363 on polycarbonate) and chemical/abrasion resistance, together with desirable processing characteristics. The coating can be 0.1 millimeter (mm) to 2 mm thick, for example, 0.25 mm to 1.5 mm, or, 0.5 mm to 1.2 mm thick. The coating can be applied on one or more sides of the substrate. For example, the substrate coating can include an acrylic hard coat.

A polymer of a conductive layer, film, or substrate, or used in the manufacture of the conductive layer, film, or substrate, (e.g., recipient substrate, donor substrate, ultraviolet curable transfer coating layer, and optional substrate coating), can include a thermoplastic polymer, a thermoset polymer, or a combination comprising at least one of the foregoing.

Possible thermoplastic polymers include, but are not limited to, oligomers, polymers, ionomers, dendrimers, copolymers such as graft copolymers, block copolymers (e.g., star block copolymers, random copolymers, and the like) or a combination comprising at least one of the foregoing. Examples of such thermoplastic polymers include, but are not limited to, polycarbonates (e.g., blends of polycarbonate (such as, polycarbonate-polybutadiene blends, copolyester polycarbonates)), polystyrenes (e.g., copolymers of polycarbonate and styrene, polyphenylene ether-polystyrene blends), polyimides (PI) (e.g., polyetherimides (PEI)), acrylonitrile-styrene-butadiene (ABS), polyalkylmethacrylates (e.g., polymethylmethacrylates (PMMA)), polyesters (e.g., copolyesters, polythioesters), polyolefins (e.g., polypropylenes (PP) and polyethylenes, high density polyethylenes (HDPE), low density polyethylenes (LDPE), linear low density polyethylenes (LLDPE)), polyethylene terephthalate (PET), polyamides (e.g., polyamideimides), polyarylates, polysulfones (e.g., polyarylsulfones, polysulfonamides), polyphenylene sulfides, polytetrafluoroethylenes, polyethers (e.g., polyether ketones (PEK), polyether etherketones (PEEK), polyethersulfones (PES)), polyacrylics, polyacetals, polybenzoxazoles (e.g., polybenzothiazinophenothiazines, polybenzothiazoles), polyoxadiazoles, polypyrazinoquinoxalines, polypyromellitimides, polyquinoxalines, polybenzimidazoles, polyoxindoles, polyoxoisoindolines (e.g., polydioxoisoindolines), polytriazines, polypyridazines, polypiperazines, polypyridines, polypiperidines, polytriazoles, polypyrazoles, polypyrrolidones, polycarboranes, polyoxabicyclononanes, polydibenzofurans, polyphthalamide, polyacetals, polyanhydrides, polyvinyls (e.g., polyvinyl ethers, polyvinyl thioethers, polyvinyl alcohols, polyvinyl ketones, polyvinyl halides, polyvinyl nitriles, polyvinyl esters, polyvinylchlorides), polysulfonates, polysulfides, polyureas, polyphosphazenes, polysilazanes, polysiloxanes, fluoropolymers (e.g., polyvinyl fluourides (PVF), polyvinylidene fluorides (PVDF), fluorinated ethylene-propylenes (FEP), polyethylene tetrafluoroethylenes (ETFE)), polyethylene naphthalates (PEN), cyclic olefin copolymers (COC), or a combination comprising at least one of the foregoing.

More particularly, a thermoplastic polymer can include, but is not limited to, polycarbonate resins (e.g., LEXAN™ polymers, including LEXAN™ CFR polymers, commercially available from SABIC's Innovative Plastics business), polyphenylene ether-polystyrene polymers (e.g., NORYL™ polymers, commercially available from SABIC's Innovative Plastics business), polyetherimide polymers (e.g., ULTEM™ polymers, commercially available from SABIC's Innovative Plastics business), polybutylene terephthalate-polycarbonate polymers (e.g., XENOY™ polymers, commercially available from SABIC's Innovative Plastics business), copolyestercarbonate polymers (e.g., LEXAN™ SLX polymers, commercially available from SABIC's Innovative Plastics business), or a combination comprising at least one of the foregoing polymers. Even more particularly, the thermoplastic polymers can include, but are not limited to, homopolymers and copolymers of a polycarbonate, a polyester, a polyacrylate, a polyamide, a polyetherimide, a polyphenylene ether, or a combination comprising at least one of the foregoing polymers. The polycarbonate can comprise copolymers of polycarbonate (e.g., polycarbonate-polysiloxane, such as polycarbonate-polysiloxane block copolymer, polycarbonate-dimethyl bisphenol cyclohexane (DMBPC) polycarbonate copolymer (e.g., LEXAN™ DMX and LEXAN™ XHT polymers commercially available from SABIC's Innovative Plastics business), polycarbonate-polyester copolymer (e.g., XYLEX™ polymers, commercially available from SABIC's Innovative Plastics business)), linear polycarbonate, branched polycarbonate, end-capped polycarbonate (e.g., nitrile end-capped polycarbonate), LNP™ THERMOCOMP™ compounds, or a combination comprising at least one of the foregoing, for example, a combination of branched and linear polycarbonate.

“Polycarbonates” as used herein further include homopolycarbonates, (wherein each R¹ in the polymer is the same), copolymers comprising different R¹ moieties in the carbonate (referred to herein as “copolycarbonates”), copolymers comprising carbonate units and other types of polymer units, such as ester units, and combinations comprising at least one of homopolycarbonates and/or copolycarbonates. As used herein, a “combination” is inclusive of blends, mixtures, alloys, reaction products, and the like.

The polycarbonate composition can further include impact modifier(s). Exemplary impact modifiers include natural rubber, fluoroelastomers, ethylene-propylene rubber (EPR), ethylene-butene rubber, ethylene-propylene-diene monomer rubber (EPDM), acrylate rubbers, hydrogenated nitrile rubber (HNBR) silicone elastomers, and elastomer-modified graft copolymers such as styrene-butadiene-styrene (SBS), styrene-butadiene rubber (SBR), styrene-ethylene-butadiene-styrene (SEBS), acrylonitrile-butadiene-styrene (ABS), acrylonitrile-ethylene-propylene-diene-styrene (AES), styrene-isoprene-styrene (SIS), methyl methacrylate-butadiene-styrene (MBS), high rubber graft (HRG), and the like. Impact modifiers are generally present in amounts of 1 to 30 wt. %, based on the total weight of the polymers in the composition.

A polymer of the film can include various additives ordinarily incorporated into polymer compositions of this type, with the proviso that the additive(s) are selected so as to not significantly adversely affect the desired properties of the polymeric composition, in particular hydrothermal resistance, water vapor transmission resistance, puncture resistance, and thermal shrinkage. Such additives can be mixed at a suitable time during the mixing of the components for forming the composition. Exemplary additives include fillers, reinforcing agents, antioxidants, heat stabilizers, light stabilizers, ultraviolet (UV) light stabilizers, plasticizers, lubricants, mold release agents, antistatic agents, colorants such as titanium dioxide, carbon black, and organic dyes, surface effect additives, radiation stabilizers, flame retardants, and anti-drip agents. A combination of additives can be used, for example a combination of a heat stabilizer, mold release agent, and ultraviolet light stabilizer. The total amount of additives (other than any impact modifier, filler, or reinforcing agents) is generally 0.01 to 5 wt. %, based on the total weight of the composition.

Light stabilizers and/or ultraviolet light (UV) absorbing stabilizers can also be used. Exemplary light stabilizer additives include benzotriazoles such as 2-(2-hydroxy-5-methylphenyl)benzotriazole, 2-(2-hydroxy-5-tert-octylphenyl)-benzotriazole and 2-hydroxy-4-n-octoxy benzophenone, or combinations comprising at least one of the foregoing light stabilizers. Light stabilizers are used in amounts of 0.01 to 5 parts by weight, based on 100 parts by weight of the total composition, excluding any filler.

UV light absorbing stabilizers include triazines, dibenzoylresorcinols (such as TINUVIN*1577 commercially available from BASF and ADK STAB LA-46 commercially available from Asahi Denka), hydroxybenzophenones; hydroxybenzotriazoles; hydroxyphenyl triazines (e.g., 2-hydroxyphenyl triazine); hydroxybenzotriazines; cyanoacrylates; oxanilides; benzoxazinones; 2-(2H-benzotriazol-2-yl)-4-(1,1,3,3-tetramethylbutyl)-phenol (CYASORB*5411); 2-hydroxy-4-n-octyloxybenzophenone (CYASORB*531); 2-[4,6-bis(2,4-dimethylphenyl)-1,3,5-triazin-2-yl]-5-(octyloxy)-phenol (CYAS ORB*1164); 2,2′-(1,4-phenylene)bis(4H-3,1-benzoxazin-4-one) (CYASORB*UV-3638); 1,3-bis[(2-cyano-3,3-diphenylacryloyl)oxy]-2,2-bis[[(2-cyano-3,3-diphenylacryloyl)oxy]methyl]propane (UVINUL*3030); 2,2′-(1,4-phenylene) bis(4H-3,1-benzoxazin-4-one); 1,3-bis[(2-cyano-3,3-diphenylacryloyl)oxy]-2,2-bis[[(2-cyano-3,3-diphenylacryloyl)oxy]methyl]propane; nano-size inorganic materials such as titanium oxide, cerium oxide, and zinc oxide, all with a particle size less than or equal to 100 nanometers, or combinations comprising at least one of the foregoing UV light absorbing stabilizers. UV light absorbing stabilizers are used in amounts of 0.01 to 5 parts by weight, based on 100 parts by weight of the total composition, excluding any filler.

The recipient substrate can include polycarbonate. The recipient substrate can include poly(methyl methacrylate) (PMMA). The recipient substrate can include polyethylene terephthalate (PET). The recipient substrate can include polyethylene naphthalate (PEN). The recipient substrate can include a combination comprising at least one of the foregoing. The donor substrate can include polyethylene terephthalate (PET). The ultraviolet curable transfer coating layer can be applied to a surface of the substrate comprising polycarbonate. The ultraviolet curable transfer coating layer can be applied to a surface of the substrate consisting of polycarbonate. The ultraviolet curable transfer coating layer can be disposed between the conductive layer and a surface of the substrate comprising polycarbonate. The conductive layer can be disposed between the ultraviolet curable transfer coating layer and a surface of the electrical circuit.

The ultraviolet curable transfer coating layer can include a multifunctional acrylate oligomer and an acrylate monomer. The ultraviolet curable transfer coating layer can include a photoinitiator. The multifunctional acrylate oligomer can include an aliphatic urethane acrylate oligomer, a pentaerythritol tetraacrylate, an aliphatic urethane acrylate, an acrylic ester, a dipentaerythritol dexaacrylate, an acrylated polymer, a trimethylolpropane triacrylate (TMPTA), a dipentaerythritol pentaacrylate ester, or a combination comprising at least one of the foregoing. In an embodiment, the multifunctional acrylate can include DOUBLEMER™ 5272 (DM5272) (commercially available from Double Bond Chemical Ind., Co., LTD., of Taipei, Taiwan, R.O.C.) which includes an aliphatic urethane acrylate oligomer in an amount from 30 weight percent (wt. %) to 50 wt. % of the multifunctional acrylate and a pentaerythritol tetraacrylate in an amount from 50 wt. % to 70 wt. % of the multifunctional acrylate.

The ultraviolet curable transfer coating layer can optionally include a polymerization initiator to promote polymerization of the acrylate components. The optional polymerization initiators can include photoinitiators that promote polymerization of the components upon exposure to ultraviolet radiation.

The ultraviolet curable transfer coating layer can include the multifunctional acrylate oligomer in an amount of 30 wt. % to 90 wt. % for example, 30 wt. % to 85 wt. %, or, 30 wt. % to 80 wt. %; the acrylate monomers in an amount of 5 wt. % to 65 wt. %, for example, 8 wt. % to 65 wt. %, or, 15 wt. % to 65 wt. %; and the optional photoinitiator present in an amount of 0 wt. % to 10 wt. %, for example, 2 wt. % to 8 wt. %, or, 3 wt. % to 7 wt. %, wherein weight is based on the total weight of the ultraviolet curable transfer coating layer.

An aliphatic urethane acrylate oligomer can include 2 to 15 acrylate functional groups, for example, 2 to 10 acrylate functional groups.

The acrylate monomer (e.g., 1,6-hexanediol diacrylate, meth(acrylate) monomer) can include 1 to 5 acrylate functional groups, for example, 1 to 3 acrylate functional group(s). In an embodiment, the acrylate monomer can be 1,6-hexanediol diacrylate (HDDA), for example, 1,6-hexanediol diacrylate commercially available from SIGMA-ALDRICH.

The multifunctional acrylate oligomer can include a compound produced by reacting an aliphatic isocyanate with an oligomeric diol such as a polyester diol or polyether diol to produce an isocyanate capped oligomer. This oligomer can then be reacted with hydroxy ethyl acrylate to produce the urethane acrylate.

The multifunctional acrylate oligomer can be an aliphatic urethane acrylate oligomer, for example, a wholly aliphatic urethane (meth)acrylate oligomer based on an aliphatic polyol, which is reacted with an aliphatic polyisocyanate and acrylated. In one embodiment, the multifunctional acrylate oligomer can be based on a polyol ether backbone. For example, an aliphatic urethane acrylate oligomer can be the reaction product of (i) an aliphatic polyol; (ii) an aliphatic polyisocyanate; and (iii) an end capping monomer capable of supplying reactive terminus. The polyol (i) can be an aliphatic polyol, which does not adversely affect the properties of the composition when cured. Examples include polyether polyols; hydrocarbon polyols; polycarbonate polyols; polyisocyanate polyols, and mixtures thereof.

The multifunctional acrylate oligomer can include an aliphatic urethane tetraacrylate (i.e., a maximum functionality of 4) that can be diluted 20% by weight with an acrylate monomer, e.g., 1,6-hexanediol diacrylate (HDDA), tripropyleneglycol diacrylate (TPGDA), and trimethylolpropane triacrylate (TMPTA). A commercially available urethane acrylate that can be used in forming the ultraviolet curable transfer coating layer can be EBECRYL™ 8405, EBECRYL™ 8311, EBECRYL™ 8807, EBECRYL™ 303, or EBECRYL™ 8402, each of which is commercially available from Allnex.

Some commercially available oligomers which can be used in the ultraviolet curable transfer coating layer can include, but are not limited to, multifunctional acrylates that are part of the following families: the PHOTOMER™ Series of aliphatic urethane acrylate oligomers from IGM Resins, Inc., St. Charles, Ill.; the Sartomer SR Series of aliphatic urethane acrylate oligomer from Sartomer Company, Exton, Pa.; the Echo Resins Series of aliphatic urethane acrylate oligomers from Echo Resins and Laboratory, Versailles, Mo.; the BR Series of aliphatic urethane acrylates from Bomar Specialties, Winsted, Conn.; the DOUBLEMER™ Series of aliphatic oligomers from Double Bond Chemical Ind., Co., LTD., of Taipei, Taiwan, R.O.C.; and the EBECRYL™ Series of aliphatic urethane acrylate oligomers from Allnex. For example, the aliphatic urethane acrylates can be KRM8452 (10 functionality, Allnex), EBECRYL™ 1290 (6 functionality, Allnex), EBECRYL™ 1290 N (6 functionality, Allnex), EBECRYL™ 512 (6 functionality, Allnex), EBECRYL™ 8702 (6 functionality, Allnex), EBECRYL™ 8405 (3 functionality, Allnex), EBECRYL™ 8402 (2 functionality, Allnex), EBECRYL™ 284 (3 functionality, Allnex), CN9010™ (Sartomer), CN9013™ (Sartomer), SR351 (Sartomer) or Laromer TMPTA (BASF), SR399 (Sartomer) dipentaerythritol pentaacrylate esters and dipentaerythritol hexaacrylate DPHA (Allnex), CN9010 (Sartomer), SR306 (tripropylene glycol diacrylate, Sartomer), CN8010 (Sartomer), CN981 (Sartomer), PM6892 (IGM), DOUBLEMER™ DM5272 (Double Bond), DOUBLEMER™ DM321HT (Double Bond), DOUBLEMER™ DM353L (Double Bond), DOUBLEMER™ DM554 (Double Bond), DOUBLEMER™ DM5222 (Double Bond), and DOUBLEMER™ DM583-1 (Double Bond).

Another component of the ultraviolet curable transfer coating layer can be an acrylate monomer having one or more acrylate or methacrylate moieties per monomer molecule. The acrylate monomer can be mono-, di-, tri-, tetra- or penta functional. In one embodiment, di-functional monomers are employed for the desired flexibility and adhesion of the coating. The monomer can be straight- or branched-chain alkyl, cyclic, or partially aromatic. The reactive monomer diluent can also comprise a combination of monomers that, on balance, result in a desired adhesion for a coating composition on the substrate, where the coating composition can cure to form a hard, flexible material having the desired properties.

The acrylate monomer can include monomers having a plurality of acrylate or methacrylate moieties. These can be di-, tri-, tetra- or penta-functional, specifically di-functional, in order to increase the crosslink density of the cured coating and therefore can also increase modulus without causing brittleness. Examples of polyfunctional monomers include, but are not limited, to C₆-C₁₂ hydrocarbon diol diacrylates or dimethacrylates such as 1,6-hexanediol diacrylate (HDDA) and 1,6-hexanediol dimethacrylate; tripropylene glycol diacrylate or dimethacrylate; neopentyl glycol diacrylate or dimethacrylate; neopentyl glycol propoxylate diacrylate or dimethacrylate; neopentyl glycol ethoxylate diacrylate or dimethacrylate; 2-phenoxylethyl (meth)acrylate; alkoxylated aliphatic (meth)acrylate; polyethylene glycol (meth)acrylate; lauryl (meth)acrylate, isodecyl (meth)acrylate, isobornyl (meth)acrylate, tridecyl (meth)acrylate; and mixtures comprising at least one of the foregoing monomers. For example, the acrylate monomer can be 1,6-hexanediol diacrylate (HDDA), alone or in combination with another monomer, such as tripropyleneglycol diacrylate (TPGDA), trimethylolpropane triacrylate (TMPTA), oligotriacrylate (OTA 480), or octyl/decyl acrylate (ODA).

Another component of the ultraviolet curable transfer coating layer can be an optional polymerization initiator such as a photoinitiator. Generally, a photoinitiator can be used if the coating composition is to be ultraviolet cured; if it is to be cured by an electron beam, the coating composition can comprise substantially no photoinitiator.

When the ultraviolet curable transfer coating layer is cured by ultraviolet light, the photoinitiator, when used in a small but effective amount to promote radiation cure, can provide reasonable cure speed without causing premature gelation of the coating composition. Further, it can be used without interfering with the optical clarity of the cured coating material. Still further, the photoinitiator can be thermally stable, non-yellowing, and efficient.

Photoinitiators can include, but are not limited to, the following: α-hydroxyketone; hydroxycyclohexylphenyl ketone; hydroxymethylphenylpropanone; dimethoxyphenylacetophenone; 2-methyl-1-[4-(methylthio)phenyl]-2-morpholinopropanone-1; 1-(4-isopropylphenyl)-2-hydroxy-2-methylpropan-1-one; 1-(4-dodecylphenyl)-2-hydroxy-2-methylpropan-1-one; 4-(2-hydroxyethoxy) phenyl-(2-hydroxy-2-propyl) ketone; diethoxyacetophenone; 2,2-di-sec-butoxyacetophenone; diethoxy-phenyl acetophenone; bis (2,6-dimethoxybenzoyl)-2,4-, 4-trimethylpentylphosphine oxide; 2,4,6-trimethylbenzoyldiphenylphosphine oxide; 2,4,6-trimethylbenzoylethoxyphenylphosphine oxide; and combinations comprising at least of the foregoing.

Exemplary photoinitiators can include phosphine oxide photoinitiators. Examples of such photoinitiators include the IRGACURE™, LUCIRIN™ and DAROCURE™ series of phosphine oxide photoinitiators available from BASF Corp.; the ADDITOL™ series from Allnex; and the ESACURE™ series of photoinitiators from Lambeth, s.p.a. Other useful photoinitiators include ketone-based photoinitiators, such as hydroxy- and alkoxyalkyl phenyl ketones, and thioalkylphenyl morpholinoalkyl ketones. Also desirable can be benzoin ether photoinitiators. Specific exemplary photoinitiators include bis(2,4,6-trimethylbenzoyl)-phenylphosphine oxide supplied as IRGACURE™ 819 by BASF or 2-hydroxy-2-methyl-1-phenyl-1-propanone supplied as ADDITOL HDMAP™ by Allnex or 1-hydroxy-cyclohexyl-phenyl-ketone supplied as IRGACURE™ 184 by BASF or RUNTECURE™ 1104 by Changzhou Runtecure chemical Co. Ltd, or 2-hydroxy-2-methyl-1-phenyl-1-propanone supplied as DAROCURE™ 1173 by BASF.

The photoinitiator can be chosen such that the curing energy is less than 2.0 Joules per square centimeter (J/cm²), and specifically less than 1.0 J/cm², when the photoinitiator is used in the designated amount.

The polymerization initiator can include peroxy-based initiators that can promote polymerization under thermal activation. Examples of useful peroxy initiators include benzoyl peroxide, dicumyl peroxide, methyl ethyl ketone peroxide, lauryl peroxide, cyclohexanone peroxide, t-butyl hydroperoxide, t-butyl benzene hydroperoxide, t-butyl peroctoate, 2,5-dimethylhexane-2,5-dihydroperoxide, 2,5-dimethyl-2,5-di(t-butylperoxy)-hex-3-yne, di-t-butylperoxide, t-butylcumyl peroxide, alpha,alpha′-bis(t-butylperoxy-m-isopropyl)benzene, 2,5-dimethyl-2,5-di(t-butylperoxy)hexane, dicumylperoxide, di(t-butylperoxy isophthalate, t-butylperoxybenzoate, 2,2-bis(t-butylperoxy)butane, 2,2-bis(t-butylperoxy)octane, 2,5-dimethyl-2,5-di(benzoylperoxy)hexane, di (trimethylsilyl)peroxide, trimethylsilylphenyltriphenylsilyl peroxide, and the like, and combinations comprising at least one of the foregoing polymerization initiators.

### EXAMPLES

The conductive film used in each example is commercially available from CIMA (SANTE™) which uses self-aligning nano-technology to obtain a silver network on a substrate. The SANTE™ film is provided with a transfer resin, which is for easy transfer from a base, e.g., PET, to another substrate, such as a polycarbonate substrate. Properties of the SANTE™ film are illustrated in Table 1.

TABLE 1
Performance Properties of SANTE ™ Film

| | Transmission (%) | Haze (%) |
|---|---|---|
| SANTE ™ with transfer resin | 80.8 | 6 |

In the examples, a 0.25 mm transparent polycarbonate film was used as the substrate with a SANTE™ nano-silver network as the conductive layer.

To apply the ultraviolet curable transfer coating layer and conductive layer to the substrate, the first surface of the recipient polycarbonate substrate and the first surface of the donor substrate was coupled, where the ultraviolet curable transfer coating was disposed therebetween. The recipient substrate and the donor substrate were pressed together, then placed into an oven at 95° C. for 1 minute. The donor substrate was removed from the recipient substrate to form a conductive multilayer sheet. UV curing was carried out using a Fusion UV machine, model F300S-6 processor using an H bulb at 300 Watts per inch, at 7 meters per minute under ambience. After UV curing, the substrate PET film was released, while the ultraviolet curable transfer coating layer remained adhered to the first surface of the substrate and the conductive coating. The conductive layer was 9-12 micrometers (μm), the thickness of the conductive layer and the ultraviolet curable transfer coating layer totals 13-15 μm.

As seen in Table 2, three kinds of ultraviolet curable transfer coating Formulations 1-3 were tested. For example, several multifunctional acrylate oligomers were evaluated as the main coating resin to offer related properties of the ultraviolet curable transfer coating layer and adhesion between the conductive layer and the ultraviolet curable transfer coating layer. Each of Formulations 1 to 3 contained 30 wt. %% HDDA (1,6-hexanediol acrylate). Each of Formulations 1 to 3 contained 5 wt. % photoinitiator Runtecure™1104 (1-hydroxy-cyclohexylphenylketone). All amounts listed in Table 2 are listed in weight percent. Table 3 includes a description of the components used in the ultraviolet curable transfer coating layer formulations. The ultraviolet curable transfer coating resins were heated at 30 minutes at 60° C. in an oven to achieve dispersion.

TABLE 2
Ultraviolet Curable Transfer Coating Layer Formulations 1-3

| | | EB8405 | | | Photoinitiator |
|---|---|---|---|---|---|
| # | HDDA | (20 wt. % HDDA) | EB8402 | PM6892 | 1104 |
| 1 | 30% | 65% | | | 5% |
| 2 | 30% | | 65% | | 5% |
| 3 | 30% | | | 65% | 5% |

TABLE 3
Ultraviolet Curable Transfer Coating
Layer Formulation Descriptions

| | EB8405 | | |
|---|---|---|---|
| | (20% wt. % HDDA) | EB8402 | PM6892 |
| | Aliphatic | Aliphatic | Aliphatic |
| | Urethane | Urethane | Urethane |
| Description | Acrylate | Acrylate | Acrylate |
| Viscosity | 4000 (60° C.) | 12500 (25° C.) | DM554 (60° C.) |
| (cps, ° C.) | | | |
| Tensile | 4000 | 3350 | NA |
| Strength | | | |
| (PSI) | | | |
| Tensile | 29 | 50 | NA |
| Elongation | | | |
| (%) | | | |

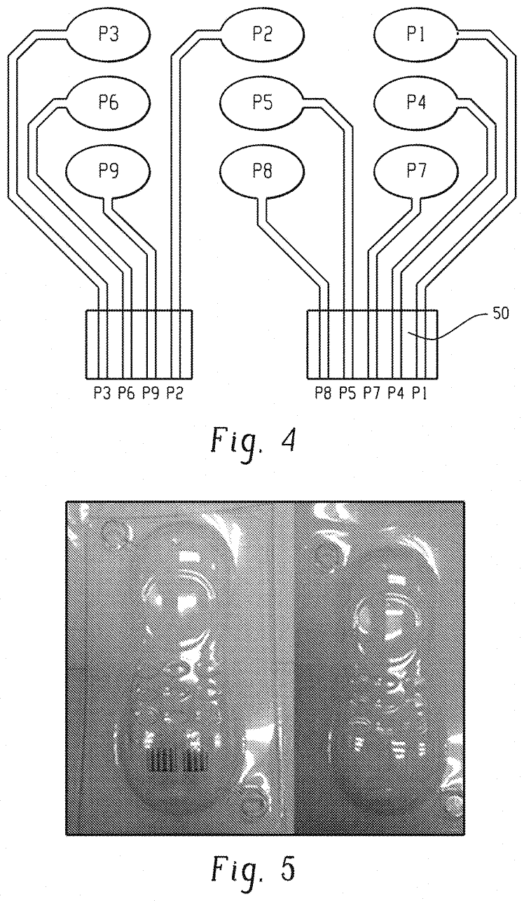

In each example, the integrated transparent conductive films were laser etched on the transparent conductive film layer. The electrical pattern on the transparent conductive film layer includes nine buttons which can realize cap sense function after laser etching the circuit. A schematic of the nine buttons is illustrated in FIG. 4, where the buttons are indicated by P1-P9. Bus bars 50 for each button are also illustrated in FIG. 4. A Delphi laser etching machine was used having a total power output of 6 Watts, current of 30%, frequency of 200 to 250 kiloHertz (kHz), pulse width of 20 nanoseconds, and scan speed of 2,000 millimeters per second (mm/s). The transparent conductive film layer comprised silver, Ag.

To thermoform the integrated transparent conductive film, the integrated transparent conductive film was placed and fixed on the clamp; the mold was raised to push the film out of the clamp before the film was heated, so that the tensile stress would be decreased in the forming process. The mold was released and began to push downward, the multilayer sheet was heated, and the temperature of the heater was set to 400° C., and after 12 seconds to 15 seconds, the multilayer sheet surface temperature can reach 160° C. to 175° C. At the same time, the vacuum on the mold is started and the mold was raised with the upper heater left on for a few seconds until the mold touches the integrated transparent conductive film. A photograph of an example of the thermoformed integrated transparent conductive film is illustrated in FIG. 5.

The ultraviolet curable transfer coating Formulations 1-3 in Table 2 were used to transfer the conductive layer onto the polycarbonate substrate by ultraviolet curing transfer technology to eventually form the transparent integrated films of Examples 1-21, after thermoforming and application of the electrical circuit. The haze and transmission results before and after thermoforming for the transparent integrated films of Examples 1-3 are listed in Table 4. The haze and transmission of the integrated films of Examples 1-3 were tested according to ASTM D1003 procedure A using CIE standard illuminant C using a Haze-Gard test device. The resin in Table 3 indicates the detailed information of the three ultraviolet curable transfer coating monomers which was used in formulations 1 to 3.

The data in table 4 shows that formulation 3 has best color performance in these three formulations. Furthermore, there is almost no change of the transmission of three samples after thermal forming, while the transferred parts have a slight hazer after thermal forming, e.g., formulation 2 shows the highest haze after thermal forming. The formability of Examples 1 and 2 were greater than that of Example 3.

TABLE 4
Transmission and Haze Results for Examples 1-3

| | | Trans- | Trans- | | |
|---|---|---|---|---|---|
| | | mission | mission | | |
| | | Before | After | Haze Before | Haze Before |
| | | Thermo- | Thermo- | Thermo- | Thermo- |
| | | forming | forming | forming | forming |
| Ex. # | Resin | (%) | (%) | (%) | (%) |
| 1 | 1 | 79.9 | 79.8 | 3.9 | 4.63 |
| 2 | 2 | 79.9 | 79 | 3.98 | 5.04 |
| 3 | 3 | 81 | 79.2 | 3.38 | 4.25 |

Transparent integrated films of Examples 4-21 were prepared as described above and include the SANTE™ conductive layer transferred to a polycarbonate substrate, one of the ultraviolet curable transfer coating resin Formulations 1-3, and an electrical circuit. The resin indicated in Tables 5-7 indicates which of Formulations 1-3 was used as the ultraviolet curable transfer coating layer in the transparent integrated film of Examples 4-21. A trace conductivity between each button illustrated in FIG. 4 of the laser etched integrated circuit was measured by a multimeter both before and after thermoforming each integrated transparent conductive film of Samples 4-21. One pin of the multimeter contacting each button was applied and another pin of multimeter contacting the corresponding bus bar trace to determine conductivity. P1-P9 represent each trace between 9 buttons and bus bar. In an example, the trace is practically invisible. Table 5 indicates a “Y” if the connection is conductive. Table 5 indicates an “X” if the connection demonstrates infinite resistance, which indicates the circuit is broken in the trace. Tables 6-7 include the resistance values for each P1-P9 both before and after thermoforming.

TABLE 5
Trace Data

| | Before Thermoforming | | | | | | | | | After Thermoforming | | | | | | | | | Resin |
|---|---|---|---|---|---|---|---|---|---|---|---|---|---|---|---|---|---|---|---|
| Ex.# | P1 | P2 | P3 | P4 | P5 | P6 | P7 | P8 | P9 | P1 | P2 | P3 | P4 | P5 | P6 | P7 | P8 | P9 | 3 |
| 4 | Y | Y | Y | Y | Y | Y | Y | Y | Y | X | Y | X | X | Y | X | Y | X | Y | 3 |
| 5 | Y | Y | Y | Y | Y | Y | Y | Y | Y | Y | Y | X | Y | Y | X | Y | X | Y | 3 |
| 6 | Y | X | Y | Y | Y | Y | Y | Y | Y | Y | X | Y | Y | Y | Y | X | X | Y | 3 |
| 7 | Y | Y | Y | Y | Y | Y | Y | Y | Y | Y | Y | Y | Y | Y | Y | Y | Y | Y | 3 |
| 8 | Y | Y | Y | Y | Y | Y | Y | Y | Y | Y | Y | Y | Y | Y | Y | Y | Y | Y | 3 |
| 9 | Y | Y | Y | Y | Y | Y | Y | Y | Y | Y | Y | Y | Y | Y | Y | Y | Y | Y | 1 |
| 10 | Y | Y | Y | Y | Y | Y | Y | Y | Y | Y | Y | Y | Y | Y | Y | Y | Y | Y | 1 |
| 11 | Y | Y | Y | Y | Y | Y | X | Y | Y | Y | Y | Y | Y | Y | Y | X | Y | Y | 1 |

TABLE 6
Electrical Resistance Values

| | Before Thermoforming | | | | | | | | | Resin |
|---|---|---|---|---|---|---|---|---|---|---|
| Ex.# | P1 | P2 | P3 | P4 | P5 | P6 | P7 | P8 | P9 | 2 |
| 12 | 187 | 152 | 191 | 141 | 120 | 145 | 76 | 62 | 83 | 2 |
| 13 | 183 | 158 | 185 | 141 | 125 | 146 | 79 | 65 | 90 | 2 |
| 14 | 189 | 171 | 187 | 145 | 124 | 147 | 78 | 69 | 92 | 2 |
| 15 | 188 | 160 | 193 | 144 | 123 | 148 | 82 | 69 | 86 | 2 |
| 16 | 184 | 157 | 186 | 143 | 124 | 141 | 84 | 68 | 86 | 2 |
| 17 | 170 | 139 | 167 | 131 | 109 | 129 | 69 | 55 | 78 | 2 |
| 18 | 188 | 166 | 191 | 142 | 127 | 147 | 81 | 68 | 93 | 2 |
| 19 | 184 | 151 | 177 | 149 | 136 | 143 | 78 | 69 | 85 | 2 |
| 20 | 164 | 147 | 178 | 127 | 111 | 136 | 74 | 61 | 84 | 2 |
| 21 | 182 | 173 | 190 | 148 | 134 | 143 | 87 | 70 | 94 | 2 |

TABLE 7
Electrical Resistance Values

| | After Thermoforming | | | | | | | | | Resin |
|---|---|---|---|---|---|---|---|---|---|---|
| Ex.# | P1 | P2 | P3 | P4 | P5 | P6 | P7 | P8 | P9 | 2 |
| 12 | 257 | 138 | 221 | 248 | 118 | 151 | X | 63 | 104 | 2 |
| 13 | 308 | 136 | 369 | 238 | 132 | 198 | 87 | 57 | 93 | 2 |
| 14 | 274 | 144 | 210 | 180 | 117 | 216 | 83 | 60 | 88 | 2 |
| 15 | X | 147 | X | X | 138 | 300 | 99 | 85 | 109 | 2 |
| 16 | 225 | 137 | 204 | 176 | 116 | 166 | 130 | 70 | X | 2 |
| 17 | 171 | 110 | 168 | 124 | 90 | 123 | 66 | 49 | 107 | 2 |
| 18 | 191 | 138 | 187 | 192 | 110 | 146 | 86 | 62 | 105 | 2 |
| 19 | 182 | 121 | 178 | X | 116 | 140 | 80 | 72 | 126 | 2 |
| 20 | 205 | 127 | 179 | 134 | 99 | 126 | 78 | 52 | 76 | 2 |
| 21 | 207 | 140 | 223 | 162 | 113 | 151 | 131 | 60 | 228 | 2 |

As indicated in Tables 5-7, the electrical resistivity values are approximately the same at each gate before and after thermoforming, indicating all of the circuits are fully functional after thermoforming.

Transparent integrated films made with the SANTE™ conductive layer, ultraviolet curable transfer coating resin formulations 1 to 3, and an electrical circuit illustrate good thermoforming performance due to good flexibility and formability.

The transparent integrated film and methods of making disclosed herein include at least the following embodiments:

### Embodiment 1

An integrated transparent conductive film, comprising: a substrate comprising a transparent thermoplastic material, wherein the substrate includes a substrate first surface and a substrate second surface; a transparent conductive layer disposed adjacent to the substrate, wherein the transparent conductive layer includes a transparent conductive layer first surface disposed on the substrate first surface; and an electrical circuit disposed on a transparent conductive layer second surface; wherein the integrated transparent conductive film has a functional electrical circuit after thermoforming.

### Embodiment 2

The integrated transparent conductive film of Embodiment 1, wherein the integrated transparent conductive film has a transmittance of greater than or equal to 80% as measured according to ASTM D1003 Procedure A using CIE standard illuminant C.

### Embodiment 3

The integrated transparent conductive film of Embodiment 1 or Embodiment 2, wherein the substrate comprises polycarbonate, poly(methyl methacrylate) (PMMA), polyethylene terephthalate (PET), polyethylene naphthalate (PEN), cyclic olefin copolymers (COC), polyetherimides (PEI), polystyrenes, polyimides, polypropylenes (PP) and polyethylenes (PE), polyvinyl fluorides (PVF), polyvinylidene fluorides (PVDF), or a combination comprising at least one of the foregoing.

### Embodiment 4

The integrated transparent conductive film of any of Embodiments 1-3, wherein the electrical circuit is conductive after thermoforming.

### Embodiment 5

The integrated transparent conductive film of any of Embodiments 1-4, wherein electrical circuit is closed after thermoforming.

### Embodiment 6

The integrated transparent conductive film of any of Embodiment 1-5, wherein the integrated conductive film further comprises an ultraviolet curable transfer coating adhered to the substrate first surface.

### Embodiment 7

The integrated transparent conductive film of Embodiment 6, wherein the ultraviolet curable transfer coating comprises a thermoset polymer.

### Embodiment 8

The integrated transparent conductive film of any of Embodiments 1-7, wherein the integrated transparent conductive film includes an abrasion resistant coating.

### Embodiment 9

The integrated transparent conductive film of any of Embodiments 1-8, wherein a thickness of the integrated conductive film is 0.01 millimeter to 5 millimeters.

### Embodiment 10

The integrated transparent conductive film of any of Embodiments 1-9, wherein the transfer resin comprises an aliphatic urethane acrylate.

### Embodiment 11

A touch screen comprising the integrated transparent conductive film of any of Embodiments 1-10.

### Embodiment 12

A method of thermoforming an article from an integrated transparent conductive film, comprising: heating the integrated transparent conductive film to a formable temperature in a mold, wherein the integrated transparent conductive film comprises a substrate comprising a transparent thermoplastic material, wherein the substrate includes a substrate first surface and a substrate second surface; a transparent conductive layer disposed adjacent to the substrate, wherein the transparent conductive layer includes a transparent conductive layer first surfaced disposed on the substrate first surface; and an electrical circuit etched onto a transparent conductive layer second surface; thermoforming the integrated transparent conductive film to the article comprising the mold shape; cooling the formed article; and removing the formed article form the mold; wherein the formed article has a functional electrical circuit after thermoforming.

### Embodiment 13

A method of thermoforming an article from an integrated transparent conductive film, comprising: applying an ultraviolet curable transfer coating to a first surface of a recipient substrate or to a first surface of a donor substrate, wherein the first surface of the donor substrate includes a conductive coating coupled thereto; pressing the first surface of the recipient substrate and the first surface of the donor substrate together to form a stack, wherein the ultraviolet curable transfer coating is disposed therebetween; heating the stack and activating the ultraviolet curable transfer coating with an ultraviolet radiation source; removing the donor substrate from the stack leaving a transparent conductive layer, wherein the ultraviolet curable transfer coating remains adhered to the first surface of the recipient substrate and to the conductive coating; laser etching an electrical circuit onto a transparent conductive layer second surface to form an integrated transparent conductive film; and thermoforming the integrated transparent conductive film to form the article, wherein the article includes a functional electrical circuit after thermoforming.

### Embodiment 14

The method of any of Embodiments 12-13, wherein thermoforming further comprises: attaching the integrated transparent conductive film to a clamp in a mold, wherein the transparent conductive layer faces a mold surface; raising the mold toward the integrated transparent conductive film; pushing the integrated transparent conductive film from the clamp before heating the film with the raised mold; lowering the mold; heating the integrated transparent conductive film to a temperature sufficient to form the integrated transparent conductive film to the mold shape; raising the mold toward the integrated transparent conductive film while under vacuum pressure; forming the article; lowering the mold and removing vacuum pressure; cooling the article; and removing the article from the mold.

### Embodiment 15

The method of any of Embodiments 12-14, wherein the integrated transparent conductive film has a transmittance of greater than or equal to 75% as measured according to ASTM D1003 Procedure A using CIE standard illuminant C.

### Embodiment 16

The method of any of Embodiments 12-15, wherein the wherein the substrate comprises polycarbonate, poly(methyl methacrylate) (PMMA), polyethylene terephthalate (PET), polyethylene naphthalate (PEN), cyclic olefin copolymers (COC), polyetherimides (PEI), polystyrenes, polyimides, polypropylenes (PP) and polyethylenes (PE), polyvinyl fluourides (PVF), polyvinylidene fluorides (PVDF), or a combination comprising at least one of the foregoing.

### Embodiment 17

The method of any of Embodiments 12-16, wherein the electrical circuit is conductive after thermoforming.

### Embodiment 18

The method of any of Embodiments 12-17, wherein electrical circuit is closed after thermoforming.

### Embodiment 19

The method of any of Embodiments 12-18, further comprising applying an abrasion resistant coating to a surface of the integrated transparent conductive film before thermoforming.

### Embodiment 20

The method of any of Embodiments 12-19, wherein a thickness of the integrated conductive film is 0.001 millimeter to 5 millimeters.

Unless otherwise specified herein, any reference to standards, testing methods and the like, such as ASTM D1003, ASTM D3359, ASTM D3363, refer to the standard, or method that is in force at the time of filing of the present application.

In general, the invention may alternately comprise, consist of, or consist essentially of, any appropriate components herein disclosed. The invention may additionally, or alternatively, be formulated so as to be devoid, or substantially free, of any components, materials, ingredients, adjuvants or species used in the prior art compositions or that are otherwise not necessary to the achievement of the function and/or objectives of the present invention.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). “Combination” is inclusive of blends, mixtures, alloys, reaction products, and the like. Furthermore, the terms “first,” “second,” and the like, herein do not denote any order, quantity, or importance, but rather are used to denote one element from another. The terms “a” and “an” and “the” herein do not denote a limitation of quantity and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the film(s) includes one or more films). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

What is claimed is:

1. A method of thermoforming an article from an integrated transparent conductive film, comprising:
applying an ultraviolet curable transfer coating to a first surface of a recipient substrate or to a first surface of a donor substrate, wherein the first surface of the donor substrate includes a conductive coating coupled thereto;
pressing the first surface of the recipient substrate and the first surface of the donor substrate together to form a stack, wherein the ultraviolet curable transfer coating is disposed therebetween;
heating the stack and activating the ultraviolet curable transfer coating with an ultraviolet radiation source;
removing the donor substrate from the stack leaving a transparent conductive layer, wherein the ultraviolet curable transfer coating remains adhered to the first surface of the recipient substrate and to the conductive coating;
laser etching an electrical circuit onto a transparent conductive layer second surface to form an integrated transparent conductive film; and
thermoforming the integrated transparent conductive film to form the article, wherein the article includes a functional electrical circuit after thermoforming.

2. The method of claim 1, wherein thermoforming further comprises:
attaching the integrated transparent conductive film to a clamp in a mold, wherein the transparent conductive layer faces a mold surface;
raising the mold toward the integrated transparent conductive film;
pushing the integrated transparent conductive film from the clamp before heating the film with the raised mold;
lowering the mold;
heating the integrated transparent conductive film to a temperature sufficient to form the integrated transparent conductive film to the mold shape;
raising the mold toward the integrated transparent conductive film while under vacuum pressure;
forming the article;
lowering the mold and removing vacuum pressure;
cooling the article; and
removing the article from the mold.

3. The method of any of claim 1, wherein the integrated transparent conductive film has a transmittance of greater than or equal to 75% as measured according to ASTM D1003 Procedure A using CIE standard illuminant C.

4. The method of any of claim 1, wherein the substrate comprises polycarbonate, poly(methyl methacrylate) (PMMA), polyethylene terephthalate (PET), polyethylene naphthalate (PEN), cyclic olefin copolymers (COC), polyetherimides (PEI), polystyrenes, polyimides, polypropylenes (PP) and polyethylenes (PE), polyvinyl fluourides (PVF), polyvinylidene fluorides (PVDF), or a combination comprising at least one of the foregoing.

5. The method of any of claim 1, wherein the electrical circuit is conductive after thermoforming.

6. The method of any of claim 1, wherein the electrical circuit is closed after thermoforming.

7. The method of any of claim 1, further comprising applying an abrasion resistant coating to a surface of the integrated transparent conductive film before thermoforming.

8. The method of any of claim 1, wherein a thickness of the integrated conductive film is 0.001 millimeter to 5 millimeters.
